(19) United States
(12) Patent Application Publication
(10) Pub. No.: US 2013/0199927 A1
(43) Pub. Date: Aug. 8, 2013

(54) METHOD OF MANUFACTURING CONDUCTIVE FILM ROLL

(71) Applicant: NITTO DENKO CORPORATION, Osaka (JP)

(72) Inventors: Nozomi Fujino, Osaka (JP); Hiroyuki Takao, Osaka (JP); Kuniaki Ishibashi, Osaka (JP)

(73) Assignee: NITTO DENKO CORPORATION, Osaka (JP)

(21) Appl. No.: 13/759,449

(22) Filed: Feb. 5, 2013

(30) Foreign Application Priority Data
Feb. 6, 2012 (JP) 2012-023078

(51) Int. Cl. C23C 14/34

(52) U.S. Cl. CPC C23C 14/34
USPC 204/192.29

(57) ABSTRACT

A method of manufacturing a conductive film roll includes a first step of sequentially laminating a first transparent conductor layer and a first copper layer on one side of a film base by sputtering and winding up a first laminated body obtained by sputtering to form a first roll, a second step of storing the first roll in an atmosphere for 30 hours or more and forming, on a surface of the first copper layer, an oxide membrane layer containing copper(I) oxide, and a third step of sequentially laminating, while unwinding the first roll, a second transparent conductor layer and a second copper layer on another side of the film base by sputtering and winding up a second laminated body obtained by sputtering to form a second roll.

### CROSS REFERENCE TO RELATED APPLICATIONS

This application claims the benefit of Japanese Application No. 2012-023078, filed Feb. 6, 2012, which is hereby incorporated by reference herein in its entirety.

### BACKGROUND OF INVENTION

1. Field of the Invention

The invention relates to a method of manufacturing a roll of a conductive film applicable to an input display unit capable of inputting information by a touch of a finger, a stylus pen, or the like.

2. Background of the Invention

In the related art, a conductive film including a transparent conductor layer formed on either face of a film base and a metal layer formed on a surface of each transparent conductor layer is known (Japanese Laid-Open Patent Publication No. 2011-060146). In employing such a conductive film for, for example, a touch sensor, it is possible to obtain a narrow bezel by processing the metal layer to form a wiring at an outer peripheral portion of a touch input area.

However, with such a conductive film of the related art, in a case where the film is wound up in a roll shape, there is a problem that adjacent film surfaces may be bonded to each other. When the bonded film surfaces are peeled apart, flaws may be produced in the transparent conductor layer in the film and may result in a decrease in quality.

### SUMMARY OF INVENTION

It is an object of the invention to provide a method of manufacturing a conductive film roll in which adjacent film surfaces are not bonded and can maintain a high quality.

To achieve the above mentioned object, a method of manufacturing a conductive film roll of the invention includes a first step of sequentially laminating a first transparent conductor layer and a first copper layer on one side of a film base by sputtering and winding up a first laminated body obtained by sputtering to form a first roll, a second step of storing the first roll in an atmosphere for 30 hours or more and forming, on a surface of the first copper layer, an oxide membrane layer containing copper(I) oxide, and a third step of sequentially laminating, while unwinding the first roll, a second transparent conductor layer and a second copper layer on another side of the film base by sputtering and winding up a second laminated body obtained by sputtering to form a second roll.

Preferably, in the second step, the first roll is stored in the atmosphere for 36 hours to 180 hours.

Also, preferably, in the second step, the oxide membrane layer having a thickness of 1 nm to 15 nm is formed.

The oxide membrane layer preferably contains greater than or equal to 50% by weight of copper(I) oxide and preferably made of a composition including copper, copper(I) oxide, copper(II) oxide, copper carbonate and copper hydroxide.

According to the invention, since a first roll in which the first laminated body is wound up is stored in the atmosphere for 30 hours or more and an oxide membrane layer containing copper(I) oxide is formed on a surface of the first copper layer, adjacent film surfaces are not be bonded in a second roll and a high quality can be maintained.

### BRIEF DESCRIPTION OF DRAWINGS

FIG. 1 is a flow chart showing a method of manufacturing a conductive film roll according to an embodiment of the invention.

FIG. 2 is a diagram schematically showing a sputtering apparatus in which the manufacturing method of FIG. 1 is employed.

FIG. 3 is a perspective view showing an exemplary conductive film roll manufactured by the sputtering apparatus of FIG. 2.

### DETAILED DESCRIPTION

Hereinafter, an embodiment of the invention will be described in detail with reference to the accompanying drawings.

The manufacturing method of the invention includes a first step of sequentially laminating, while unwinding an initial roll of a film base, a first transparent conductor layer and a first copper layer on one side of a film base by sputtering in a low pressure gas and winding up a first laminated body obtained by sputtering to form a first roll, a second step of storing the first roll in the atmosphere for 30 hours or more and forming, on a surface of the first copper layer, an oxide membrane layer containing copper(I) oxide, and a third step of sequentially laminating, while unwinding the first roll, a second transparent conductor layer and a second copper layer on another side of the film base by sputtering in a low pressure gas and winding up a second laminated body obtained by sputtering to form a second roll.

The sputtering is usually performed in a low pressure gas. The low pressure gas is an air pressure environment of 1/10 or below of the standard atmosphere (101325 Pa), and preferably 1 10⁻⁵ Pa to 1 Pa.

With the manufacturing method of the invention, there is an advantageous effect that, by forming an oxide membrane layer containing copper(I) oxide on a surface of a first copper layer (second step), bonding does not occur even if a slip sheet is not inserted between conductive film surfaces when winding up a second laminated body into a roll to form a second roll (third step).

This is presumed to be because, with the oxide membrane layer containing copper(I) oxide without free electron being interposed between the first copper layer and the second copper layer, which are adjacent to each other, metallic bonding between the first copper layer and the second copper layer can be prevented.

As long as the aforementioned first to third steps are included, the manufacturing method of the invention may include another step between the steps or after the third step within a scope in which an advantageous effect of the invention is achieved.

Next, each step of the manufacturing method of the present embodiment will be described with reference to a flow chart of FIG. 1.

(1) First Step

First, a first step of the invention is a step of sequentially laminating, while unwinding an initial roll of a film base, a first transparent conductor layer and a first copper layer on one side of a film base by sputtering in a low pressure gas of, for example, 1 10⁻⁵ Pa to 1 Pa, and winding up a first laminated body obtained by sputtering to form a first roll (step S11). With such a step, since the first transparent conductor layer and the first copper layer are sequentially laminated, it is possible to improve adhesiveness between the layers, and in addition, to reduce foreign materials entering between the layers.

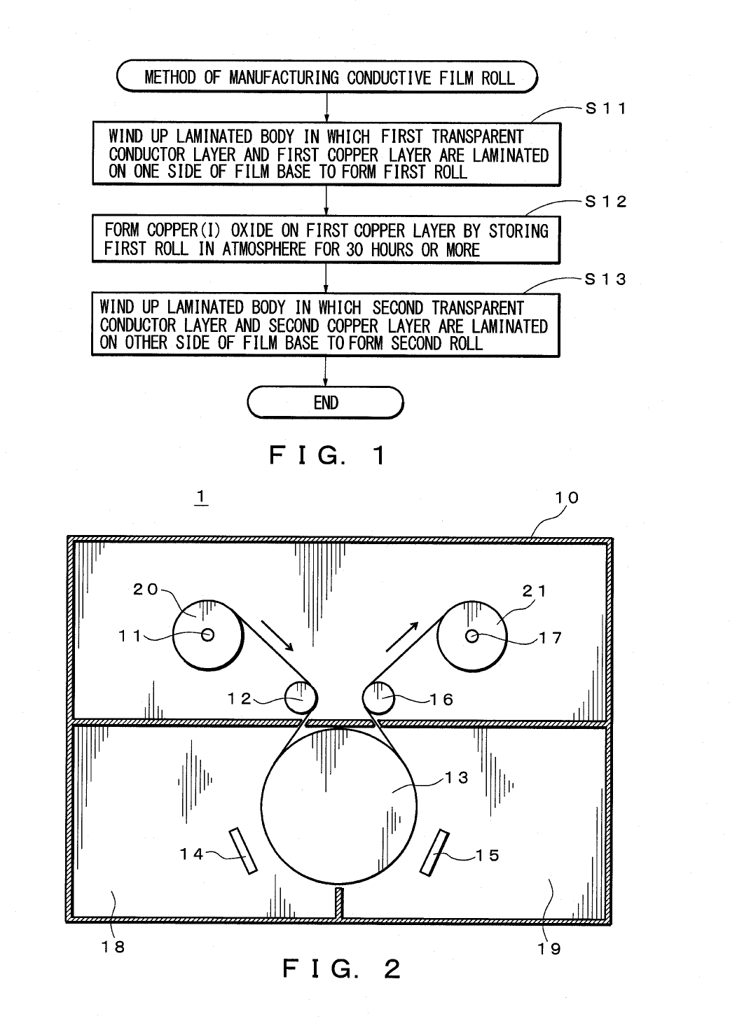

The first step is preferably carried out with the sputtering apparatus of FIG. 2. It is to be noted that, the sputtering apparatus of FIG. 2 is shown by way of example, and a sputtering apparatus in which the manufacturing method of the invention is employed is not limited to the apparatus shown in FIG. 2.

In FIG. 2, a sputtering apparatus 1 includes a chamber 10 for creating a low-pressure environment (e.g., 1 10⁻⁵ Pa to 1 Pa), a holding portion 11 that holds an initial roll 20 in which an elongated film base is wound up, a guide roll 12 that guides the film base which is transported from the initial roll 20 to a film formation roll, which will be described later, a film formation roll 13 which is disposed downstream, in a transport direction, of the guide roll 12 and which is temperature controllable, a target material (first target material) 14 disposed so as to oppose the film formation roll and electrically connected to a direct-current power supply, not shown, a target material (second target material) 15 which is disposed downstream, in the transport direction, of the target material 14 and which is electrically connected to a direct-current power supply, not shown, a guide roll 16 disposed downstream of the film formation roll 13, and a holding portion 17 which winds up the film base in which the first transparent conductor layer and the first copper layer are formed to form a roll (first roll) 21 and which holds the roll.

The sputtering apparatus 1 is provided with two processing compartments 18, 19 in the chamber 10 to perform sputtering under mutually different conditions using the target material 14 and the target material 15.

The sputtering is a method in which, for example, in the sputtering apparatus 1, in a low pressure gas, a cation in a plasma generated by applying a voltage (for example, −400 V to −100 V) across the film formation roll and each target material is collided with a target material, which is a negative electrode, and a substance ejected from a surface of the aforementioned target material is deposited onto the film base.

Continuously laminating the first transparent conductor layer and the first copper layer on one side of the film base can be achieved by, for example, in the sputtering apparatus described above, using a fired target of indium oxide and tin oxide as the target material 14 and an oxygen-free copper target as the target material 15.

(2) Second Step

A second step of the invention is a step of storing the first roll, in which the first laminated body is wound up, in the atmosphere (e.g., 88000 Pa to 105000 Pa, 10 to 50 C) for 30 hours or more, and forming, on a surface of the first copper layer, an oxide membrane layer containing copper(I) oxide (step S12).

With such a step, it is presumed that, due to action of oxygen molecules intruding laterally to the first roll while being stored, the surface of the first copper layer is gradually oxidized to form the oxide membrane layer. The thickness of the oxide membrane layer necessary for obtaining the conductive film roll that does not bond is preferably greater than or equal to 1 nm (e.g., 1 nm to 15 nm).

The copper(I) oxide is a univalent copper oxide represented by a chemical formula: Cu2O. The content of copper(I) oxide in the oxide membrane layer is preferably greater than or equal to 50% by weight, and more preferably, greater than or equal to 60% by weight. The oxide membrane layer is normally made of a composition including, in addition to copper(I) oxide, copper (non-oxidized copper), copper(II) oxide, copper carbonate and copper hydroxide, or the like.

In order to obtain a conductive film roll that does not bond, a time during which the first roll is stored is 30 hours or more and preferably 36 hours to 180 hours. The storage time represents a time between the termination of the first step and the initiation of the third step, and it is for example a period of time between opening the sputtering apparatus to the atmosphere in the first step and an initiation of a pressure reduction of the sputtering apparatus in the third step.

There is no limitation to the aforementioned method of storing the first roll, and the first roll may be left at rest or, where appropriate, may be moved depending on the requirements of the storage facility or for a more efficient transition to the subsequent third step.

(3) Third Step

A third step of the invention is a step of, while unwinding the first roll, sequentially laminating a second transparent conductor layer and a second copper layer are on the other side of the film base by sputtering in a low pressure gas of 1 10⁻⁵ Pa to 1 Pa and winding up a second laminated body obtained by sputtering to form a second roll (step S13). In performing the third step, for example, with the sputtering apparatus of FIG. 2, the first roll is placed at the holding portion 11, the second transparent conductor layer and the second copper layer are continuously laminated on the other side of the film base, and the laminated body obtained by sputtering is wound up by the holding portion 17 to form a second roll.

With the second roll (i.e., conductive film roll) obtained with such a step, since an oxide membrane layer containing copper(I) oxide is interposed between the first copper layer and second copper layer, there is an advantageous effect that bonding does not occur without requiring a slip sheet or the like to be inserted.

Preferably, a sputtering apparatus and conditions similar to those used in the first step are employed for the method of sequentially laminating the second transparent conductor layer and second copper layer onto the film base.

(4) Conductive Film Roll

The conductive film roll obtained by the manufacturing method of the invention is constituted by winding up an elongated conductive film.

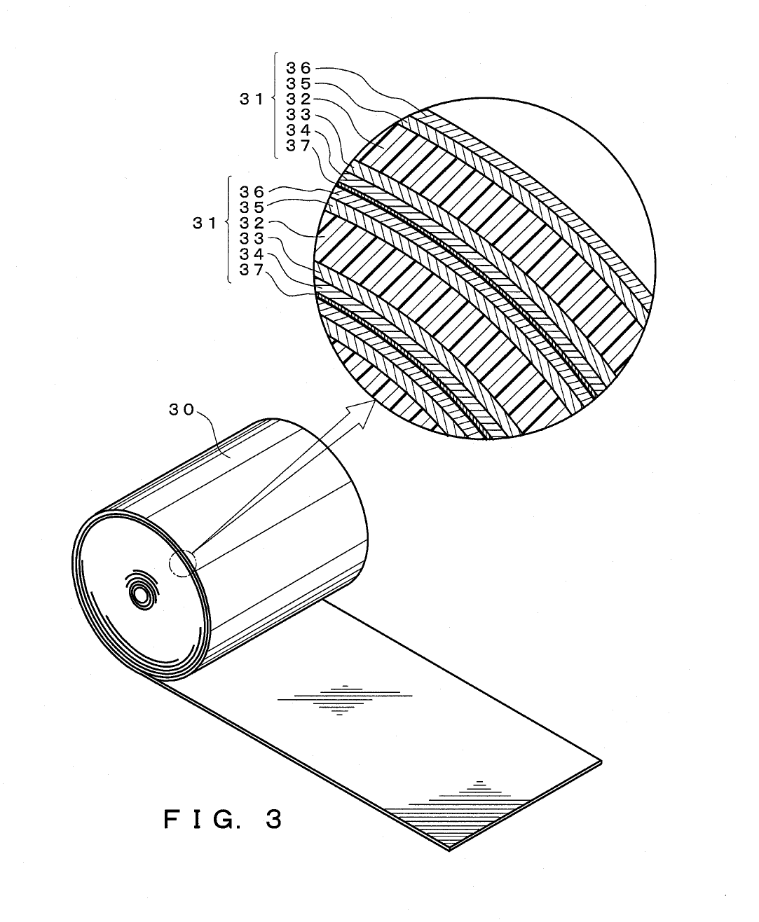

FIG. 3 is a perspective view showing an exemplary conductive film roll manufactured by the sputtering apparatus of FIG. 2.

In FIG. 3, a conductive film 31 includes a film base 32, a transparent conductor layer (first transparent conductor layer) 33 formed on one side of film base, a copper layer (first copper layer) 34 formed on a side of the transparent conductor layer 33 opposite to the film base 32, a transparent conductor layer (second transparent conductor layer) 35 formed on the other side of the film base 32, a copper layer (second copper layer) 36 formed on a side of the transparent conductor layer 35 opposite to the film base 32, and an oxide membrane layer 37 formed on a side of the copper layer 34 opposite to the transparent conductor layer 33 and containing copper(I) oxide. With the conductive film roll 30 constituted by winding up the conductive film 31, the oxide membrane layer 37 is interposed between the copper layer 34 and the copper layer 36.

A material forming the film base 32 is preferably polyethylene terephthalate (110), polycycloolefin (3900) or polycarbonate (9000). A numerical value indicated in parentheses represents an oxygen permeability for a film base of a thickness 100 μm made of each material. The film base may include other layers on the surface.

From a point of view of facilitating the forming of the oxide membrane layer 37 on a surface of the copper layer 34 in the second step, the film base 32 has an oxygen permeability of preferably 100 to 20,000 ml/m² day MPa, and more preferably, 2,000 to 15,000 ml/m² day MPa. The oxygen permeability can be obtained in conformity with JIS K7126B.

A material forming the transparent conductor layers 33 and 35 is preferably an indium tin oxide, an indium zinc oxide or a composite oxide of indium oxide-zinc oxide. Each of the transparent conductor layers 33 and 35 has a thickness of preferably 20 nm to 80 nm.

The copper layers 34 and 36 are, for example, when used in a touch panel, used for forming a wiring at an outer peripheral portion of a touch input area by etching each copper layer. Each of the copper layers 34 and 36 has a thickness of preferably 20 nm to 300 nm.

As has been described above, according to the present embodiment, since an oxide membrane layer containing copper(I) oxide is formed on a surface of the first copper layer by storing the first roll, in which the first laminated body is wound up, in the atmosphere for 30 hours or more, the film surfaces adjacent to each other are not bonded in the second roll and a high quality can be maintained.

In the above description, a manufacturing method of the conductive film roll of the present embodiment has been described. However, the invention is not limited to the embodiment described above, and various alterations and modifications can be made based on a technical concept of the invention.

Hereinafter, examples of the invention will be described.

### EXAMPLE 1

An initial roll of a film base made of a polycycloolefin film (manufactured by Zeon Corporation, product name: “ZEONOR” (registered trademark)) having a thickness of 100 μm, a length of 1,000 m and an oxygen permeability of 3,900 ml/m² day MPa was placed in a sputtering apparatus. An argon gas was enclosed in a chamber of the sputtering apparatus and adjusted to a low-pressure environment of 0.4 Pa. While unwinding the initial roll, a first transparent conductor layer composed of an indium tin oxide layer having a thickness of 20 nm and a first copper layer having a thickness of 50 nm were sequentially laminated on one side of a film base by sputtering. The first laminated body obtained by sputtering was wound up to form a first roll.

Then, the first roll was stored in the atmosphere (102700 Pa, 23 C) for 72 hours and an oxide membrane layer containing copper(I) oxide was formed on a surface of the first copper layer. The oxide membrane layer obtained by sputtering had a content of copper(I) oxide of 82% by weight and a thickness of 1.7 nm.

Subsequently, the first roll was placed in a sputtering apparatus similar to that of the above and under conditions similar to those of the above, while unwinding the first roll, a second transparent conductor layer composed of an indium tin oxide layer of a thickness of 20 nm and a second copper layer of a thickness of 50 nm were sequentially laminated on the other side of the film base by sputtering. The second laminated body obtained by sputtering was wound up to form a second roll.

### EXAMPLE 2

Except that the storage time of the first roll was 36 hours, a conductive film roll was manufactured in a manner similar to that of Example 1.

### COMPARATIVE EXAMPLE 1

Except that the storage time of the first roll was 24 hours, a conductive film roll was manufactured in a manner similar to that of Example 1.

### COMPARATIVE EXAMPLE 2

Except that the storage time of the first roll was 3 hours, a conductive film roll was manufactured in a manner similar to that of Example 1.

Next, Examples 1 and 2 and Comparative Examples 1 and 2 were measured and observed with the following methods.

(1) Measurement of Thickness of Oxide Membrane Layer and Content of Copper(I) Oxide

Using an X-ray photoelectron spectroscopy analyzer device (manufactured by ULVAC-PHI, Inc, product name: “QuanteraSXM”), a thickness of the oxide membrane layer and a percent by weight of copper(I) oxide contained in the oxide membrane layer were measured.

(2) Bonding of Conductive Film Roll

Inspection was carried out by unwinding the conductive film from the conductive film roll and observing a roll surface.

(3) Measurement of Thicknesses of Transparent Conductor Layer, Copper Layer and Film Base

The thicknesses of the transparent conductor layer and the copper layer were measured by carrying out a cross-section observation with a transmission electron microscope (manufactured by Hitachi, Ltd., product name: “H-7650”). Also, the thickness of the copper layer was measured with a film thickness meter (manufactured by Ozaki MFG. Co., Ltd., Peacock digital dial gauge DG-205).

Results of evaluation carried out by the aforementioned methods (1) to (3) are shown in Table 1.

TABLE 1

| | STORAGE TIME | BONDING | |
|---|---|---|---|
| | (SECOND STEP) | OF ROLL | DETERMINATION |
| EXAMPLE 1 | 72 HOURS | NO | ◯ (OK) |
| EXAMPLE 2 | 36 HOURS | NO | ◯ (OK) |
| COMPARATIVE | 24 HOURS | YES | X (NG) |
| EXAMPLE 1 | | | |
| COMPARATIVE | 3 HOURS | YES | X (NG) |
| EXAMPLE 2 | | | |

As shown in Table 1, bonding did not occur in the conductive film roll of Examples 1 and 2 in which the storage time of the first roll was 30 hours or more. On the other hand, bonding occurred in the conductive film roll of Comparative Examples 1 and 2 in which the storage time of the first roll was less than 30 hours. During the unwinding of the first roll in which bonding has occurred, a peeling-off sound was produced and numerous flaws were produced in a surface of the transparent conductor layer.

Therefore, in the manufacturing method of the invention, assuming that the storage time of the first roll in the atmosphere was 30 hours or more, it was found that the adjacent film surfaces do not bond with each other and a high quality can be maintained.

### INDUSTRIAL APPLICABILITY

With the conductive film roll obtained by the manufacturing method of the invention, preferably, the unwound conductive film is cut into a display size and used in touch sensors of a capacitive type or the like.

What is claimed is:

1. A method of manufacturing a conductive film roll, comprising:
a first step of sequentially laminating a first transparent conductor layer and a first copper layer on one side of a film base by sputtering and winding up a first laminated body obtained by sputtering to form a first roll;
a second step of storing the first roll in an atmosphere for 30 hours or more and forming, on a surface of the first copper layer, an oxide membrane layer containing copper(I) oxide; and
a third step of sequentially laminating, while unwinding the first roll, a second transparent conductor layer and a second copper layer on another side of the film base by sputtering and winding up a second laminated body obtained by sputtering to form a second roll.

2. The method of manufacturing a conductive film roll according to claim 1, wherein, in the second step, the first roll is stored in the atmosphere for 36 hours to 180 hours.

3. The method of manufacturing a conductive film roll according to claim 1, wherein, in the second step, the oxide membrane layer having a thickness of 1 nm to 15 nm is formed.

4. The method of manufacturing a conductive film roll according to claim 1, wherein, the oxide membrane layer contains greater than or equal to 50% by weight of copper(I) oxide.

5. The method of manufacturing a conductive film roll according to claim 1, wherein, the oxide membrane layer is made of a composition including copper, copper(I) oxide, copper(II) oxide, copper carbonate and copper hydroxide.
